(19) United States
(12) Patent Application Publication
(10) Pub. No.: US 2023/0318711 A1
(43) Pub. Date: Oct. 5, 2023

(54) Optical Transceiver Methods and Apparatus for Integrated Optical Links

(71) Applicant: Fathom Radiant, PBC, Boulder, CO (US)

(72) Inventors: Ross Walker, Louisville, CO (US); Ryan Boesch, Louisville, CO (US); Soheil Hashemi, Broomfield, CO (US)

(21) Appl. No.: 18/296,306

(22) Filed: Apr. 5, 2023

Related U.S. Application Data
(60) Provisional application No. 63/327,593, filed on Apr. 5, 2022.
(60) Provisional application No. 63/327,628, filed on Apr. 5, 2022.
(60) Provisional application No. 63/334,481, filed on Apr. 25, 2022.

(51) Int. Cl. H04B 10/43; H01S 5/183

(52) U.S. Cl. CPC H04B 10/43; H01S 5/183

(57) ABSTRACT

The architecture integrates electronic circuitry with highly parallel (>100 elements) surface-normal optoelectronic devices for the purpose of transmitting optical communication signals over a transmission channel. Local electronic circuitry is integrated very close (<100 um) to the optical element, which simplifies the electrical characteristics such that the electronic circuitry can perform better in terms of power dissipation, area utilization, and accuracy of the transmitted and received optical emissions.

This application claims the benefit of U.S. Patent Application 63/327,593, filed 5 Apr. 2022; 63/327,628 filed 2022 Apr. 5; and 63/334,481 filed 2022 Apr. 25, and incorporates them herein by reference.

### BACKGROUND OF THE INVENTION

### Field of the Invention

The present invention relates to transceivers of integrated optical links.

### Discussion of Related Art

Generally radiative optical communication elements are placed far from electronic circuitry in separate packages of some type, e.g. individually packaged optical detectors or emitters. There is also work toward silicon photonics where the optical elements including optical modulators and a source are combined directly with integrated circuits on the same chip.

### SUMMARY OF THE INVENTION

The invention comprises an electrical and optical communication transceiver system constructed with an integrated circuit upon which highly parallel optical source and detector elements are assembled. Here the integrated circuit is referred to as a “chip” and is generally fabricated in a standard complementary metal oxide semiconductor (CMOS) foundry before additional processing is performed to assemble the optical elements. Example “highly parallel” optical source and detector elements have counts of more than 100 optical elements per chip and support bidirectional communication rates of more than 0.1 trillion bits per second per square millimeter of chip surface area underneath the optical elements. An example would be a 3 mm×3 mm chip with 50 bidirectional lanes all operating at 20 Gbps. Another example would be a 2 mm×2 mm chip with 50 bidirectional lanes all operating at 112 Gbps.

Embodiments are based on custom chips designed specifically to be combined with advanced packaging techniques that allow the chip's electronic circuitry to be integrated very close to the optical elements, thereby simplifying the electrical characteristics such that the electronic circuitry can perform better in terms of power dissipation, area utilization, and accuracy of the transmitted and received optical signals. The optical elements transmit and receive light in an orthogonal geometric fashion with respect to the surface plane of the chip, described herein as “surface-normal” operation. Surface-normal optical communication with highly parallel optical elements enables highly parallel communication signals to be directed onto and off of the chip. The optical signals can encode digital and/or analog data or combinations of the two. The signals can be communicated in a broad range of optical transmission channels including but not limited to multi-core fiber optic assemblies, single-core fiber optic assemblies, free space, and optical device assemblies. In a preferred embodiment described here, the surface-normal optical signals are communicated into and out of a wavelength division multiplexing (WDM) optical device assembly that is assembled on top of the chip after assembly of the optical elements. The WDM device attaches to the chip on one side and connects to one or more optical fibers arranged in an assembly on another side.

Multiple wavelengths are superimposed in each optical fiber core and separated from each other by the WDM device, while each optical element assembled on the chip primarily interfaces with a single wavelength.

An optical transceiver comprises an integrated circuit (IC) with multiple optical elements including optical emitters and optical detectors assembled onto its surface. The optical emitters emit optical signals in a surface normal direction to the surface of the IC and the optical detectors receive optical signals in a surface normal direction to the surface of the IC.

An optical multiplexer multiplexes multiple multi-wavelength optical output signals from the optical emitters into an optical fiber. The multiplexer also de-multiplexes multiple multi-wavelength optical input signals from an optical fiber into individual optical detectors. Electronic transmitters drive the optical emitters with one electronic transmitter corresponding to one optical emitter; and electronic receivers receive and decode signals from the optical detectors with one electronic receiver corresponding to one optical detector. The optical transceiver has at least 100 optical elements.

The electronic transmitters are located within 100 um their corresponding optical emitters, and the electronic receivers are within 100 um of their corresponding optical detectors. The optical fibers may have a single optical core. The optical emitters are vertical-cavity surface-emitting lasers and the optical detectors are photodiodes.

The electronic transmitters may include a programmable current steering driver circuit that encodes data bits into current levels, a current steering driver circuit with a vertical-cavity surface-emitting laser emulation branch that uses feedback to improve the accuracy with which the branch emulates the electrical characteristics of the vertical-cavity surface-emitting laser, a current steering circuit, and a programmable current steering driver circuit that uses equalization, for example currents to improve the accuracy of the data transmission. They may also have a current steering circuit configured to use clock pulses.

The electronic receivers may include a transimpedance amplifier with programmable gain and a signal conditioning circuit that uses a limiting amplifier, as well as a signal conditioning circuit including decision circuitry to decide the values of received data bits. The decision circuitry may be timed by clocks.

The optical signals from the optical emitters can also be coupled directly into optical fibers, and the optical signals can be coupled directly from optical fibers into the optical detectors. The fibers may each have a single optical fiber core, and may connect to a free-space optical system.

The optical emitters might be VCSELs with multiple wavelengths which are coupled by the optical multiplexer into optical fibers each having a single core or multiple cores.

### BRIEF DESCRIPTION OF THE DRAWINGS

FIG. 1 is an isometric schematic view of an optical transceiver apparatus for parallel optical communication.

FIG. 2 is a block diagram of a single lane of an optical transceiver apparatus.

FIG. 3 is a schematic block diagram illustrating an optoelectronic data transmitter.

FIG. 4 is a simplified schematic of an embodiment of the driver electronics.

FIG. 5 is a diagram of a local optical detector with a local electrical receiver.

FIG. 6 is a simplified schematic of an embodiment of the detection electronics.

### DETAILED DESCRIPTION OF THE INVENTION

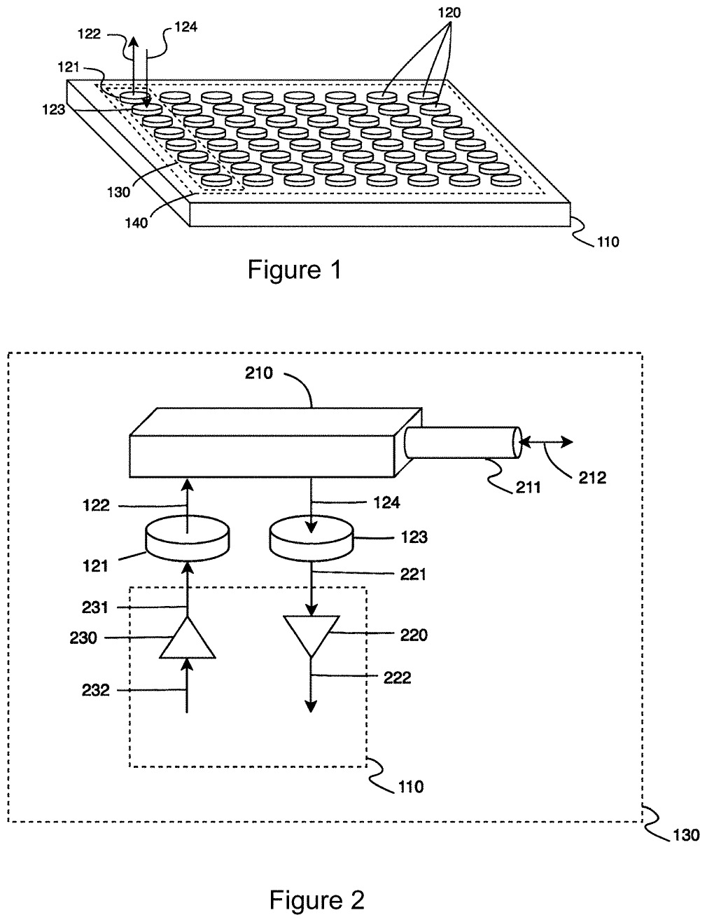

FIG. 1 shows an isometric schematic view of an optical transceiver apparatus for parallel optical communication. Optoelectronic elements (120) are assembled on the surface of an integrated circuit (110) in a highly parallel manner, for example greater than 100 elements per chip. The optoelectronic elements (120) are composed of some combination of optical emitters (121) emitting signals in a surface normal direction (122) and optical detectors (123) receiving optical signals in a surface normal direction (124). Those elements can be grouped into subsets (130) forming separate optical links or the entire group of elements (140) can form a single optical link.

FIG. 2 shows a block diagram of a single lane of an optical transceiver apparatus, having one optical emitter (121) and one optical detector (123) connected to the integrated circuit (110) and connected to an optical wavelength division multiplexer (210) that is connected to an optical fiber (211) that may have one or more optical fiber cores (212). The structure shown in FIG. 2 generally describes how the optical elements (120) are interfaced to the optical wavelength division multiplexer (210), optical fibers (211), and optical fiber cores (212) but there are many possibilities for the number of each of these elements. FIG. 2 also shows an electrical transmitter (230) that is located in the integrated circuit layer (110) below the optical emitter (121) and which drives the emitter (121) with an electrical signal (231) so that the emitter (121) forms a surface normal optical signal (122). Similarly, FIG. 2 shows an electrical receiver (220) that is located in the integrated circuit layer (110) below the optical detector (123) and which receives an electrical signal (221) from the optical detector (123) which is converted from the surface normal optical signal (124).

The electrical transmitter (230) is located near the optical emitter (121) and the electrical receiver (220) is near the optical detector (123) for example within 100 um. This results in reduced parasitics allowing for higher-speed operation and/or lower power consumption with a more compact and less complex circuit design. Multiple optical signals (122) from multiple optical emitters (121) are coupled into an optical wavelength division multiplexer (210) which in turn couples those signals into the optical fiber (211) and optical fiber core (212). The multiplexer (210) is compact, for example in the range of 100 um to 5 mm thick. The multiplexer (210) also demultiplexes multiple signals (124) from the optical fiber (211) and optical fiber core (212) and couples them to their respective optical detectors (123).

As an alternative, the optical fiber (211) may have multiple optical fiber cores (212) with one or more optical wavelengths multiplexed onto each optical fiber core (212). As another alternative, multiple optical fibers (211) may be connected to each integrated circuit (110) through the optical wavelength division multiplexer (210). These optical fibers (211) may each have one optical fiber core (212) or more than one optical fiber core (212).

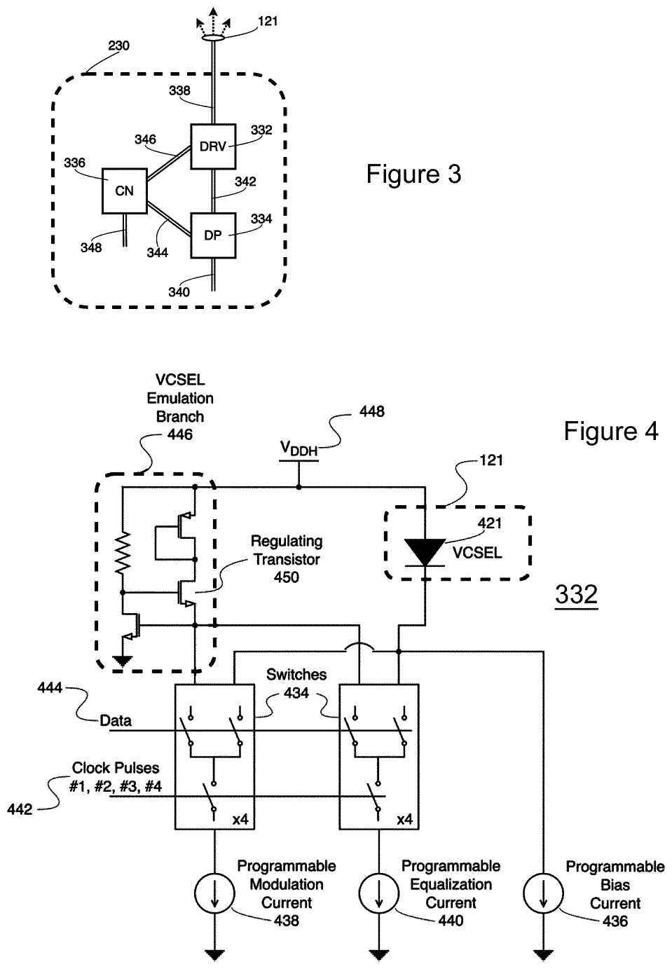

FIG. 3 shows a local optical emitter (121) with a corresponding local electrical transmitter (230). The diagram in FIG. 3 shows a local optical emitter device (121) that is operated by the electrical transmitter (230), the latter of which is portioned into driver electronics (332), datapath electronics (334), and control electronics (336). In addition to these electronics, there are electrical conductor and insulator components that connect these elements together (338, 340, 342, 344, 346, and 348).

The driver electronics (332) can be designed to drive electrical signals (231) as voltages, currents, or a combination of both into the optical emitter device (121). The driver electronics (332) connect to the optical emitter (121) through some number of conductors (338) that can be fabricated through a combination of standard integrated circuit metal and insulation layers as well as specialized conductor and insulator materials e.g. deposited onto a previously fabricated chip.

The datapath electronics (334) organize incoming data from the overall system that are connected to the datapath electronics (334) through a set of conductors and insulators (340). The datapath presents the organized data to the driver electronics (332) through a set of conductors and insulators (342). The datapath electronics (334) receives timing and configuration information from the control electronics (336) through a set of conductors and insulators (344). The driver electronics (332) receive configuration signals from the control electronics (336) through a set of conductors and insulators (346). The control electronics are connected to the rest of the integrated circuit (110) through a set of conductors and insulators (348).

An embodiment of the optical emitter device (121) is a micro-scale vertical-cavity surface-emitting laser (VCSEL) (421) (see FIG. 4) with two electrically conducting terminals: a cathode and an anode. However, many other embodiments are possible including but not limited to light emitting diodes, laser diodes, optical modulators connected to an external optical source, etc., which may be connected to a varying number of conductors (338).

An embodiment of control electronics (336) is a set of digital registers, buffers, and digital-to-analog converters that store and drive in configuration settings for current levels in the driver electronics. The control electronics connect to the driver electronics through a set of conductors and insulators (346). The control electronics also interact with datapath electronics (334) to reset the state of the datapath and provide timing information to organize the data that flow therein. A separate set of conductors and insulators (344) connect the control electronics to the datapath electronics. The control electronics are connected to the rest of the integrated circuit (110) through a set of conductors and insulators (348). In an embodiment, some of the configuration settings in the control electronics are shared by two instantiations of the driver electronics, each connected to a different optical element. However, many other embodiments are possible including but not limited to fully digital configuration, fully analog configuration, a combination of the two, and different portioning of shared and independent configuration functionality between one or more instantiation of the driver electronics, etc.

An embodiment of datapath electronics (334) receives an 8-bit byte from the overall system through 8 parallel conductors (340), timed by the control electronics (336). The datapath serializes the byte into 4 conductors that connect to the driver electronics for feeding the four parallel driver circuits therein. However, many other embodiments are possible including but not limited to different numbers of parallel bits received from the overall system, different numbers of serialized data streams, and different mechanisms of resetting the state of the datapath or not resetting at all.

FIG. 4 is a simplified schematic showing an embodiment of the driver electronics (332) connected to a VCSEL (421) as the optical emitter (121). The circuit shown in FIG. 4 is a current-mode driver circuit with switches (434) that are activated sequentially by the control electronics (336) shown in FIG. 3 to transmit digital data bits one at a time after the bits are organized in time by the datapath electronics (334).

This scheme uses drive currents comprising a programmable bias current (436), a programmable modulation current for a “1” bit (438), and a programmable equalization current (440) that adds drive current to the current bit if the previous bit was a “0”. The invention does not rely on this embodiment, however, since many other embodiments are possible including but not limited to combining multiple bits into different amplitude levels for a single drive pulse, the removal or addition of equalization signals, different numbers of parallel drivers, voltage mode driving, switching of charged or uncharged capacitances into the optical emitter (121), switching resistances into the optical emitter (121), etc. The programmable currents (436, 438, 440) can be calibrated in both offline and online manners to provide support for a wide range of process, voltage, and temperature operating conditions. The clock pulses (442) shown in FIG. 4 are used for overall timing of the transmitted data (444). In different embodiments, the clock pulses may be generated and synchronized locally on the integrated circuit (110) or may be extracted from a signal (124) that is received by one of the optical detectors (123).

FIG. 4 shows a VCSEL emulation branch (446) constructed with transistors and a resistor. It is designed to match the characteristics of the VCSEL (421), minimizing the impact to the power supply while regulating the emulation node output to within the thin-oxide voltage limits of advanced processes. This regulation is maintained even for supply voltage VDDH (448) in excess of the thick-oxide supply limit of advanced process nodes, with the VCSEL emulation branch (446) providing sufficient voltage drop to protect the devices. The VCSEL emulation branch (446) uses feedback to control the conductivity of the regulating transistor (450).

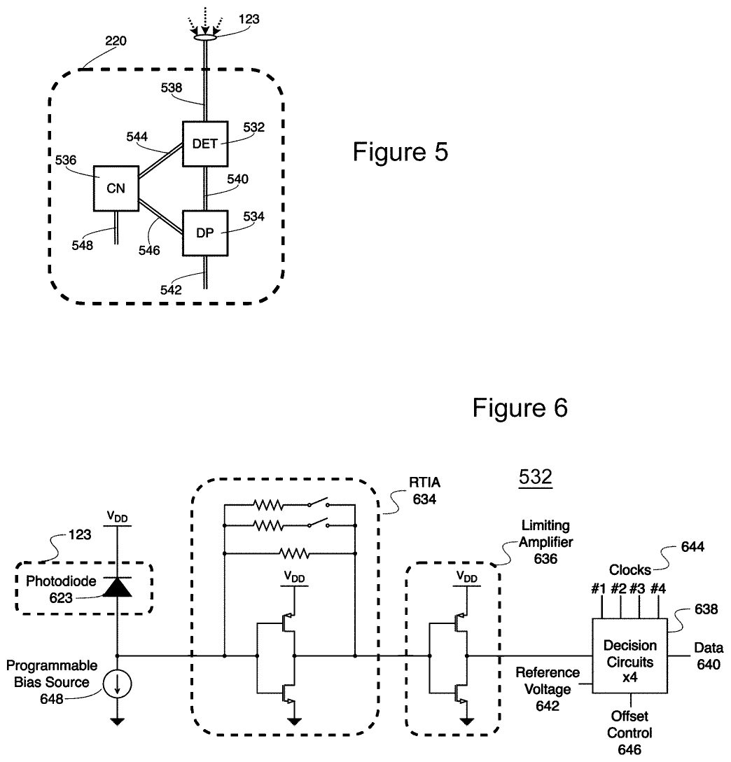

FIG. 5 shows a local optical detector (123) with its corresponding local electrical receiver (220). FIG. 5 shows the electrical receiver (220) connected to a local optical detector (123). The electrical receiver (220) is portioned into detection electronics (532), datapath electronics (534), and control electronics (536). In addition to these electronics, there are electrical conductor and insulator components that connect these elements together (538, 540, 542, 544, 546, and 548).

The detection electronics (532) can be designed to sense voltages, currents, or a combination of both from the optical detector (123). The detection electronics connect to the optical detector (123) through some number of conductors (538) that can be fabricated through a combination of standard integrated circuit metal and insulation layers as well as specialized conductor and insulator materials e.g. deposited onto a previously fabricated chip.

The datapath electronics (534) organize incoming data sensed by the detection circuitry (532), which is connected to the datapath through a set of conductors and insulators (540). The datapath electronics (534) presents the organized data to the rest of the integrated circuit (110) through a set of conductors and insulators (542). The datapath receives timing and configuration information from the control electronics (536) over a set of conductors and insulators (546). The detection electronics (532) receive configuration signals from the control electronics (536) through a set of conductors and insulators (544). The control electronics are connected to the rest of the integrated circuit (110) through a set of conductors and insulators (548).

A useful embodiment of the optical detector (123) is a photodiode with a cathode and an anode. However, many other embodiments are possible including but not limited to thermocouples, metal and semiconductor bolometers, molecular radiometers, and optic-acoustic detectors, etc., which may be connected to a varying number of conductors (538).

FIG. 6 is a simplified schematic showing an embodiment of the detection electronics (532) connected to a photodiode (623) embodying the optical detector (123). In this embodiment, the detection electronics (532) consist of a resistive feedback transimpedance amplifier (RTIA) (634) followed by a limiting amplifier (636) and decision circuits (638). In some embodiments, the limiting amplifier (636) may be portioned into multiple individual stages or may be omitted altogether. The decision circuits (638) are arranged in 4 parallel copies that are activated sequentially by control electronics (536) to receive digital data (640) one bit at a time. This preferred scheme converts the sensed current from the photodiode (623) to a voltage and compares it to an adjustable reference voltage (642) to decode whether the incoming bit is a “1” or “0”. In other embodiments, the encoding of data may be more complex e.g. using a different number of levels to encode the data (640). The clocks (644) shown in FIG. 6 define the points in time at which the data (640) decisions are made by the decision circuits (638). In different embodiments, the clocks may be generated and synchronized locally on the integrated circuit (110) or may be extracted from a signal (124) that is received by one of the optical detectors (123).

In this embodiment the decision circuits (638) use digital offset control (646) so that a single reference voltage (642) may be used. In addition, the programmable bias source (648) at the RTIA input compensates for offset of the RTIA and the average received current from the photodiode (623). The gain of the RTIA is programmable with configurable switches to select the parallel feedback resistance value. The invention does not rely on this preferred embodiment, however, since many other embodiments are possible including but not limited to e.g. sensing multiple bits with each circuit by using a multilevel modulated optical waveform, the addition of equalization signals, different numbers of parallel circuits, voltage mode sensing, removal or addition of offset reduction circuitry of different types, etc.

An embodiment of control electronics (536) is a set of digital registers, buffers, and digital-to-analog converters that store and drive in configuration settings for the gain and offset reduction functions in the detection circuitry. The control electronics connect to the detection electronics through a set of conductors and insulators (544). The control electronics also interact with the datapath electronics (534) to reset the state of the datapath and provide timing information to organize the data that flow therein. A separate set of conductors and insulators (546) connect the control electronics to the datapath electronics.

The control electronics are connected to the rest of the system through a set of conductors and insulators (548). Many other embodiments are possible including but not limited to fully digital configuration, fully analog configuration, a combination of the two, and different portioning of shared and independent configuration functionality between one or more instantiation of the detection electronics or between the parallel circuits in one instantiation of the detection electronics, etc.

An embodiment of datapath electronics (534) organizes an 8-bit byte out of each two consecutive sets of 4 bits sensed at the detection electronics. The 8-bit byte is transferred to the overall system through 8 parallel conductors, timed by clock signals from the control electronics. However, many other embodiments are possible including but not limited to different numbers of parallel bits at each step of organization, and different mechanisms of resetting the state of the datapath or not resetting at all.

Features of the present invention include utilization of a current steering VCSEL transmitter (230) for dense highly parallel surface-normal opto-electronic transceivers. The surface normal stacking of the VCSELs (421) results in reduced parasitics and higher speed with lower energy per bit using otherwise standard circuit architecture. Another advantage is an improved VCSEL emulation branch (446), which better matches the local VCSEL device (421) while also allowing common anode voltages above the I/O supply tolerated in advanced silicon logic processes. The present invention provides better performance in terms of power dissipation, area utilization, and accuracy of the induced optical emission and higher common anode supply in advanced silicon logic processes.

Features of the present invention include local electronic circuitry combined with surface normal out-of-plane optical communication optoelectronic elements, and large scale optical communication systems with pitch-matched miniaturized optoelectronic elements and local electronic circuitry. Advantages include reduced parasitics in between the optoelectronic element and local circuitry and batch fabrication of a multichannel optical communication system.

While the exemplary preferred embodiments of the present invention are described herein with particularity, those skilled in the art will appreciate various changes, additions, and applications other than those specifically mentioned, which are within the spirit of this invention.

What is claimed is:

1. An optical transceiver comprising:
an integrated circuit (IC) with multiple optical elements assembled onto a surface of said IC;
wherein the optical elements include optical emitters configured to emit optical signals in a surface normal direction to the surface of the IC;
wherein the optical elements further include optical detectors configured to receive optical signals in a surface normal direction to the surface of the IC;
an optical multiplexer configured to multiplex a plurality of multi-wavelength optical output signals from said optical emitters into an optical fiber;
an optical multiplexer configured to de-multiplex a plurality of multi-wavelength optical input signals from an optical fiber into individual optical detectors;
electronic transmitters to drive said optical emitters, with one electronic transmitter corresponding to one optical emitter; and
electronic receivers to receive and decode signals from said optical detectors, with one electronic receiver corresponding to one optical detector.

2. The optical transceiver of claim 1 having 100 optical elements.

3. The optical transceiver of claim 2, wherein the electronic transmitters are located within 100 um of their corresponding optical emitters and wherein the electronic receivers are located within 100 um of their corresponding optical detectors.

4. The optical transceiver of claim 1 wherein the optical fibers have a single optical fiber core.

5. The optical transceiver of claim 1, wherein the optical emitters are vertical-cavity surface-emitting lasers (VCSELs) and wherein the optical detectors are photodiodes.

6. The optical transceiver of claim 1, wherein the electronic transmitters each comprise:
a programmable current steering driver circuit that encodes data bits into current levels;
a current steering driver circuit with a vertical-cavity surface-emitting laser emulation branch that uses feedback to improve the accuracy with which the branch emulates the electrical characteristics of the vertical-cavity surface-emitting laser;
a current steering circuit; and
a programmable current steering driver circuit that uses equalization.

7. The optical transceiver of claim 6 wherein the current steering driver uses currents to improve the accuracy of the data transmission.

8. The optical transceiver of claim 6 further comprising a current steering circuit configured to use clock pulses.

9. The optical transceiver of claim 1, wherein the electronic receivers each comprise:
a transimpedance amplifier with programmable gain; and
a signal conditioning circuit that uses a limiting amplifier.

10. The optical transceiver of claim 9, wherein the electronic receivers further comprise a signal conditioning circuit including decision circuitry configured to decide the values of received data bits.

11. The optical transceiver of claim 10 wherein the decision circuitry is timed by clocks.

12. The optical transceiver of claim 1, wherein the optical emitters are VCSELs with multiple wavelengths which are coupled by the optical multiplexer into optical fibers each having a single optical fiber core.

13. The optical transceiver of claim 1, wherein the optical emitters are VCSELs with multiple wavelengths which are coupled by the optical multiplexer into optical fibers each having multiple optical fiber cores.

14. An optical transceiver comprising:
an integrated circuit (IC) with multiple optical elements assembled onto a surface of said IC;
wherein the optical elements include optical emitters configured to emit optical signals in a surface normal direction to the surface of the IC;
wherein the optical elements further include optical detectors configured to receive optical signals in a surface normal direction to the surface of the IC;
wherein the optical elements are coupled to optical fibers;
electronic transmitters to drive said optical emitters, with one electronic transmitter corresponding to one optical emitter; and
electronic receivers to receive and decode signals from said optical detectors, with one electronic receiver corresponding to one optical detector.

15. The optical transceiver of claim 14, wherein the surface normal signals from the optical emitters are coupled into the optical fibers through a free-space optical system.

16. The optical transceiver of claim 14, wherein the surface normal signals incident to the optical detectors are coupled from optical fibers each having a single optical fiber core through a free-space optical system.

17. The optical transceiver of claim 14, wherein the optical elements are coupled directly into optical fibers.
